(19) United States
(12) Patent Application Publication
(10) Pub. No.: US 2007/0241321 A1
(43) Pub. Date: Oct. 18, 2007

(54) Light-emitting diode structure

(75) Inventors: Cheng-Huang Kuo, Tainan County (TW); Gou-Chung Chi, Hsinchu County (TW); Chao-Min Chen, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: National Central University, Taoyuan (TW)

(21) Appl. No.: 11/549,637

(22) Filed: Oct. 13, 2006

(30) Foreign Application Priority Data
Apr. 18, 2006 (TW) 95113732

(51) Int. Cl. H01L 29/06

(52) U.S. Cl. 257/13

(57) ABSTRACT

A light-emitting diode (LED) structure including a substrate, a first type doped semiconductor layer, an active layer, a second type doped semiconductor layer and a transparent conductive layer is provided. The first type doped semiconductor layer is located on the substrate. The active layer is located on the first type doped semiconductor layer. The second type doped semiconductor layer is located on the active layer, and the transparent conductive layer is disposed on the second type doped semiconductor layer. A portion of the transparent conductive layer and the second type doped semiconductor layer underneath the transparent conductive layer are removed by etching, so as to make the transparent conductive layer to be a mesh structure and to make a surface of the second type doped semiconductor layer to be a rough surface. The occurrence of total internal reflection inside the LED is reduced.

### CROSS-REFERENCE TO RELATED APPLICATION

This application claims the priority benefit of Taiwan application serial no. 95113732, filed on Apr. 18, 2006. All disclosure of the Taiwan application is incorporated herein by reference.

### BACKGROUND OF THE INVENTION

1. Field of Invention

The present invention relates to an LED structure. More particularly, the present invention relates to an LED structure with a preferred luminous efficiency.

2. Description of Related Art

Recently, light-emitting diodes (LEDs) using GaN-base compound semiconductors such as GaN, AlGaN, InGaN have attracted more attention. Group III nitrides are materials of wide bandgap, and the light emitting wavelength thereof ranges from UV light to infrared ray, i.e., covers nearly the entire spectrum of visible light. Moreover, compared with conventional bulbs, the LED has absolute advantages such as small volume, long service life, low voltage/current drive, being uneasy to be cracked, mercury free (no contamination) and good luminous efficiency (power-saving), so LEDs are widely used in industry.

FIG. 1A is a top view of a conventional LED. FIG. 1B is a schematic sectional view along the section line I-I′ in FIG. 1A. FIG. 1C is a schematic view of the light transmission path of the LED in FIG. 1A. First, referring to FIGS. 1A and 1B, a conventional LED 100 includes a substrate 110, a patterned first type doped semiconductor layer 122, an active layer 124, a second type doped semiconductor layer 126, and a transparent conductive layer 130. The substrate 110 can be an Al₂O₃ substrate. The patterned first type doped semiconductor layer 122 is disposed on the substrate 110. Further, the active layer 124 is disposed on the protruding portion of the doped semiconductor layer 122, the second type doped semiconductor layer 126 is disposed on the active layer 124, and the transparent conductive layer 130 is disposed on the second type doped semiconductor layer 126. It should be noted that the aforementioned first type doped semiconductor layer 122 and the second type doped semiconductor layer 126 are doped semiconductor layers of different types. For example, if the first type doped semiconductor layer 122 is an N-type doped semiconductor layer, the second type doped semiconductor layer 126 is a P-type doped semiconductor layer.

Specifically, usually pads 142 and 144 are respectively disposed on the second type doped semiconductor layer 126 and on the first type doped semiconductor layer 122 uncovered by the second type doped semiconductor layer 126. The pads 142 and 144 are made of metal materials. It should be noted that the conventional LED usually is electrically connected to a circuit board or other carriers by wire bonding or flip-chip bonding, and thus the pads 142 and 144 function as media for the LED 100 to be electrically connected to a circuit board or other carriers.

Referring to FIG. 1C, when a forward bias is applied to pads 142 and 144 of the LED 100, the LED 100 is turned on, such that the active layer 124 emits light. Seen from FIG. 1C, the forward light L1 generated by the active layer 124 can directly penetrate through the second type doped semiconductor layer 126 and the transparent conductive layer 130 to the outside. Since photons generated in the active layer 124 will be partially absorbed by transparent conductive layer 130, it is necessary to increases the transmittance of transparent conductive layer 130. However, as for other lights, for example, lights L2 and L3, a total internal reflection inside the transparent conductive layer 130 is likely to occur, and the light loss resulting from the total reflection may significantly reduce the luminous efficiency of the LED 100.

Therefore, how to improve the LED structure to enhance the total luminous efficiency of the LED is an urgent problem.

### SUMMARY OF THE INVENTION

The objective of the present invention is to provide an LED structure, wherein a portion of the transparent conductive layer and the second type doped semiconductor layer underneath the transparent conductive layer are removed to make the transparent conductive layer to be a mesh structure and a surface of the second type doped semiconductor layer to be a rough surface. Accordingly, the occurrence of total internal reflection inside the LED is reduced, thus enhancing the light extraction efficiency and luminous efficiency of the LED.

In order to achieve the above and other objectives, the present invention provides an LED structure, which comprises a substrate, a first type doped semiconductor layer, an active layer, a second type doped semiconductor layer, a transparent conductive layer, a first electrode, and a second electrode. The first type doped semiconductor layer is disposed on the substrate. The active layer is disposed on the first type doped semiconductor layer. The second type doped semiconductor layer is disposed on the active layer, wherein a surface of the second type doped semiconductor layer has a plurality of recesses. The transparent conductive layer is disposed on the surface of the second type doped semiconductor layer and has a plurality of openings, wherein each of the recesses of the second type doped semiconductor layer is exposed from each of the openings. The first electrode is disposed on the first type doped semiconductor layer and is electrically connected to the first type doped semiconductor layer. The second electrode is disposed on the transparent conductive layer and is electrically connected to the transparent conductive layer. The first electrode and the second electrode are electrically isolated from each other.

In one embodiment of the present invention, the material of the substrate comprises one of Si, glass, GaAs, GaN, AlGaAs, GaP, SiC, InP, BN, ZnO, Al₂O₃, and AlN.

In one embodiment of the present invention, the first type doped semiconductor layer is an N-type semiconductor layer, and the second type doped semiconductor layer is a P-type semiconductor layer.

In one embodiment of the present invention, the first type doped semiconductor layer comprises a buffer layer, a first contact layer, and a first confinement layer, wherein the buffer layer is disposed on the substrate, the first contact layer is disposed on the buffer layer, and the confinement layer is disposed on the first contact layer.

In one embodiment of the present invention, the active layer includes a multiple quantum well (MQW) structure.

In one embodiment of the present invention, the material of the transparent conductive layer is selected from a group consisting of Ni/Au, TiN, Pd/Au/Pt/Au, ITO, CTO, AgInO₂/Sn, ZnO:Al (AZO), NiO/ZnO:Al (AZO), AgInO₂:Sn, In₂O₃:Zn (IZO), CuAlO₂, LaCuOS, NiO, CuGaO₂, and SrCu₂O₂.

In one embodiment of the present invention, the transparent conductive layer is of a mesh structure.

In one embodiment of the present invention, a sidewall of each recess of the transparent conductive layer is aligned with a sidewall of each corresponding opening.

In one embodiment of the present invention, the openings expose a portion of the surface of the second type doped semiconductor layer.

In one embodiment of the present invention, the surface of the recess exposed from each opening of the transparent conductive layer is a rough surface.

The above-mentioned LED is a planar LED. However, the present invention also provides a vertical LED. The structure and material of each element of the vertical LED is substantially the same as those of the planar LED, and the difference lies in that the two electrodes of the planar LED are disposed at the same side of the LED, while the two electrodes of the vertical LED are disposed respectively on the top and bottom sides of the LED.

In the LED of the present invention, a portion of the transparent conductive layer and the second type doped semiconductor layer underneath the transparent conductive layer are removed by etching, so as to make the transparent conductive layer to be a mesh structure and a surface of the second type doped semiconductor layer to be a rough surface. Since the transparent conductive layer and the second type doped semiconductor layer are not completely flat films, the occurrence of total internal reflection inside the LED is avoided, thus enhancing the light extraction efficiency and the luminous efficiency of the LED.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a conventional LED.

FIG. 1B is a schematic sectional view along the section line I-I′ in FIG. 1A.

FIG. 1C is a schematic view of the light-emitting region of the LED in FIG. 1A.

FIG. 2 is a schematic sectional view of an LED according to a preferred embodiment of the present invention.

FIG. 3 is a detail sectional view of the first type doped semiconductor layer, the active layer, and the second type doped semiconductor layer of the LED chip in FIG. 2.

FIGS. 4A and 4B are schematic sectional views of an LED according to other embodiments of the present invention.

FIG. 5 is a schematic sectional view of an LED according to another preferred embodiment of the present invention.

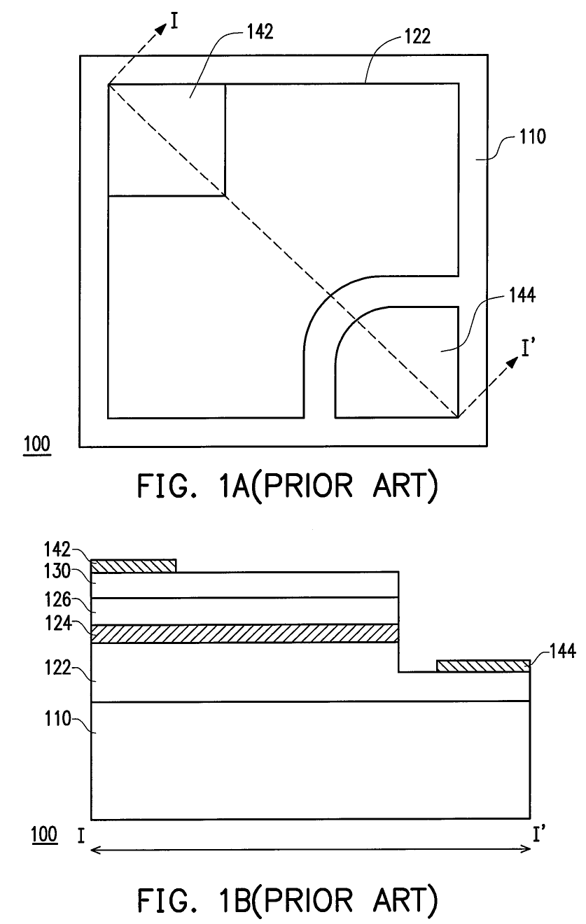

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

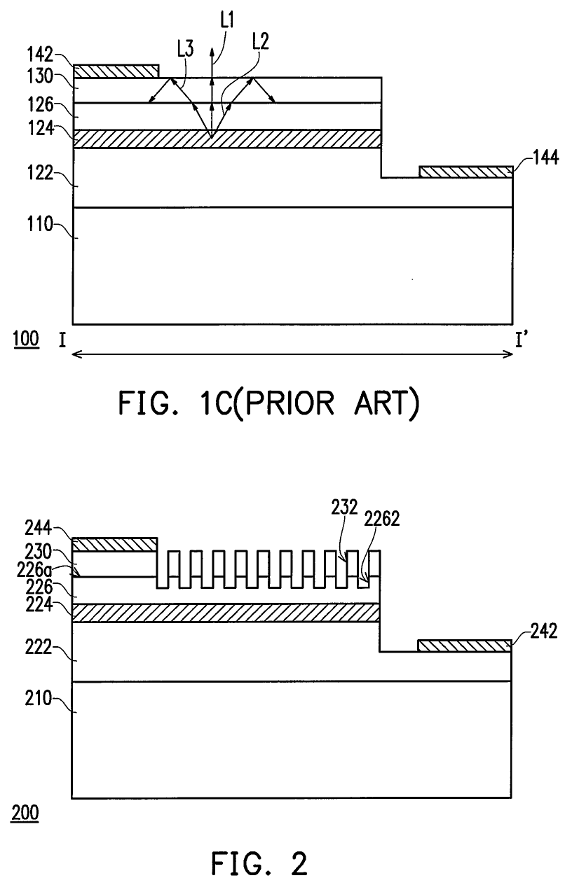

FIG. 2 is a schematic sectional view of the LED according to a preferred embodiment of the present invention. Referring to FIG. 2, an LED 200 of the present invention is a planar LED, which mainly comprises a substrate 210, a patterned first type doped semiconductor layer 222, an active layer 224, a second type doped semiconductor layer 226, a transparent conductive layer 230, a first electrode 242, and a second electrode 244. The patterned first type doped semiconductor layer 222 is disposed on the substrate 210. The active layer 224 is disposed on a portion of the first type doped semiconductor layer 222. The second type doped semiconductor layer 226 is disposed on the active layer 224, and a plurality of recesses 2262 is disposed on a surface 226a of the second type doped semiconductor layer 226. The transparent conductive layer 230 is disposed on the surface 226a of the second type doped semiconductor layer 226 and has a plurality of openings 232, wherein each of the recesses 2262 of the second type doped semiconductor layer 226 is exposed from each of the above openings 232. The first electrode 242 is disposed on the first type doped semiconductor layer 222 uncovered by the active layer 224 and is electrically connected to the first type doped semiconductor layer 222. The second electrode 244 is disposed on the transparent conductive layer 230 and is electrically connected to the transparent conductive layer 230. Moreover, the first electrode 242 and the second electrode 244 are electrically isolated from each other.

In the LED 200 of the present invention, a portion of the transparent conductive layer 230 and the second type doped semiconductor layer 226 underneath the transparent conductive layer 230 are removed by etching, so as to make the transparent conductive layer 230 to be a mesh structure and a surface of the second type doped semiconductor layer 226 to be a rough surface. Accordingly, most lights emitted from the active layer 224 can be directly projected through the LED 200, so as to reduce the occurrence of total internal reflection inside the LED 200, thus enhancing the light extraction efficiency and the luminous efficiency of the LED.

The structures of the aforementioned members are illustrated in detail below, which are not intended to limit the scope of the present invention. It is apparent to those skilled in the art that proper modifications and variations can be made with reference to the disclosure of the present invention within the scope thereof.

The material of the substrate 210 can be, for example, semiconductor or non-semiconductor materials such as Si, glass, GaAs, GaN, AlGaAs, GaP, SiC, InP, BN, ZnO, Al₂O₃, or AlN. The patterned first type doped semiconductor layer 222 is disposed on the substrate 210. In one embodiment of the present invention, the first type doped semiconductor layer 222 is, for example, an N-type semiconductor layer.

The active layer 224 is disposed on the protruding portion of the first type doped semiconductor layer 222. In one embodiment of the present invention, the active layer 224 is, for example, a GaN/InGaN MQW. The second type doped semiconductor layer 226 is disposed on the active layer 224, and the surface 226a thereof has a plurality of recesses 2262 to form a rough surface. In one embodiment of the present invention, the second type doped semiconductor layer 226 is, for example, a P-type semiconductor layer.

The transparent conductive layer 230 is disposed on the surface 226a of the second type doped semiconductor layer 226 and has a plurality of openings 232, such that each of the recesses 2262 of the second type doped semiconductor layer 226 is exposed from each of the above-mentioned openings 232. Moreover, the material of the transparent conductive layer 230 is selected from a group consisting of Ni/Au, TiN, Pd/Au/Pt/Au, ITO, CTO, AgInO₂/Sn, ZnO:Al (AZO), NiO/ZnO:Al (AZO), AgInO₂:Sn, In₂O₃:Zn (IZO), CuAlO₂, LaCuOS, NiO, CuGaO₂, SrCu₂O₂, and another suitable transparent conductive material. In one embodiment of the present invention, a portion of the transparent conductive layer 230 and the second type doped semiconductor layer 226 underneath the transparent conductive layer are removed by etching, so as to make the transparent conductive layer 230 to be a mesh structure and to make the surface 226a of the second type doped semiconductor layer 226 to have a plurality of recesses 2262. Besides, the sidewall of each of the recesses 2262 is aligned with the sidewall of each corresponding opening 232. Further, in order to enhance the light extraction efficiency of the LED, the surfaces of the recesses 2262 is made to be a rough surface to avoid the occurrence of total internal reflection.

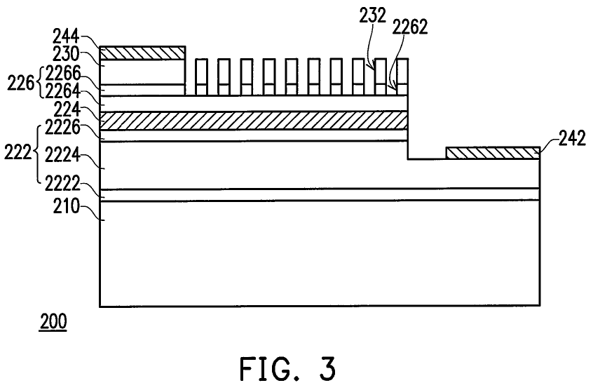

FIG. 3 is a detail sectional view of the first type doped semiconductor layer, the active layer, and the second type doped semiconductor layer of the LED chip in FIG. 2. Referring to FIG. 3, in one embodiment of the present invention, the first type doped semiconductor layer 222 comprises a buffer layer 2222, a first contact layer 2224, and a first confinement layer 2226. The buffer layer 2222 is disposed on the substrate 210. The first contact layer 2224 is disposed on the buffer layer 2222. The first confinement layer 2226 is disposed on the first contact layer 2224 and contains an N-type doped GaN. The active layer 224 is disposed on a protruding portion of the first confinement layer 2226. The second type doped semiconductor layer 226 includes a second confinement layer 2264 and a second contact layer 2266. The second confinement layer 2264 is disposed on the active layer 224 and contains a P-type doped GaN. The second contact layer 2266 is disposed on the second confinement layer 2264 and contains a P-type doped GaN.

Referring to FIG. 2, the first electrode 242 is disposed on the first type doped semiconductor layer 222 uncovered by the active layer 224 and is electrically connected to the first type doped semiconductor layer 222. In one embodiment of the present invention, the material of the first electrode 242 is, for example, Ti/Al alloy, and so on. The second electrode 244 is disposed on the transparent conductive layer 230 and is electrically connected to the transparent conductive layer 230. The first electrode 242 and the second electrode 244 are electrically isolated from each other. Further, the material of the second electrode 244 comprises one of Ni/Au, Ni/Pd, Pd/Au, Pt/Au, Cr/Au, Cr/Pt/Au, Cr/Pd/Au, Sn/Au, TiN, TiWN_{X}, and WSi_{X}.

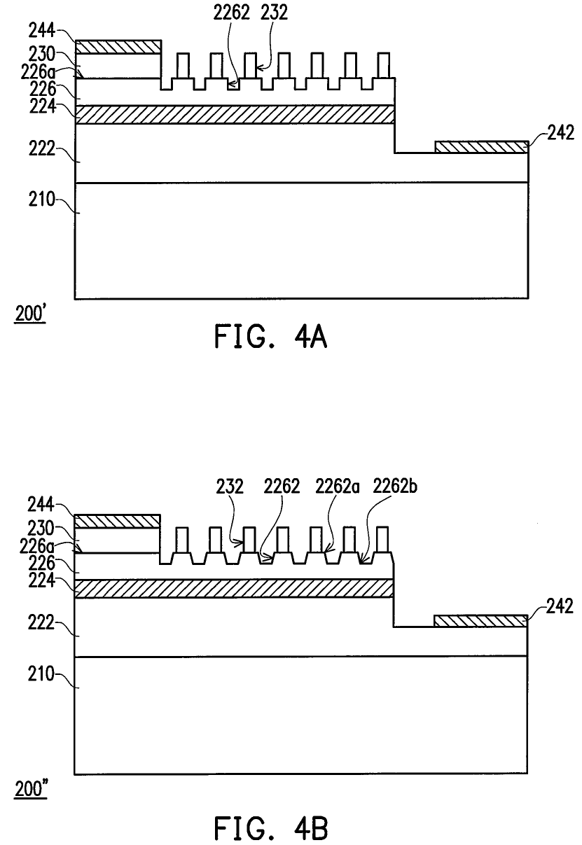

FIGS. 4A and 4B are schematic sectional views of the LED according to other embodiments of the present invention. The structure of an LED 200′ in FIG. 4A is similar to that of the LED 200 in FIG. 2. As such, the opening 232 not only exposes the recess 2262, but also exposes a portion of the surface 226a of the second type doped semiconductor layer 226.

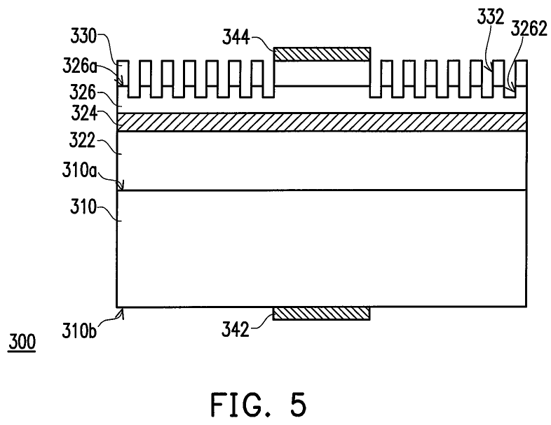

FIG. 5 is a schematic sectional view of the LED according to another preferred embodiment of the present invention. The structure of an LED 300 in FIG. 5 is similar to that of the LED 200 in FIG. 2. However, the LED 200 in FIG. 2 is a planar LED while the LED 300 in FIG. 5 is a vertical LED.

Referring to FIG. 5, the LED 300 mainly comprises a conductive substrate 310, a first type doped semiconductor layer 322, an active layer 324, a second type doped semiconductor layer 326, a transparent conductive layer 330, an electrode 342, and an electrode 344.

The conductive substrate 310 has a first surface 310a and a second surface 310b. In one embodiment of the present invention, the conductive substrate 310 is selected from a group consisting of a Si substrate, SiC substrate, GaN substrate, ZnO substrate, Al₂O₃ substrate, and another suitable conductive substrate. The first type doped semiconductor layer 322 is disposed on the first surface 310a of the conductive substrate 310. The active layer 324 is disposed on the first type doped semiconductor layer 322. The second type doped semiconductor layer 326 is disposed on the active layer 324. Further, a surface 326a of the second type doped semiconductor layer 326 has a plurality of recesses 3262.

The transparent conductive layer 330 is disposed on the surface 326a of the second type doped semiconductor layer 326 and has a plurality of openings 332, such that each of the recesses 3262 of the second type doped semiconductor layer 326 is exposed from one of the openings 332. Likewise, a portion of the transparent conductive layer 330 and the second type doped semiconductor layer 326 underneath the transparent conductive layer 330 are removed by etching, so as to make the transparent conductive layer 330 to be a mesh structure and the surface 326a of the second type doped semiconductor layer 326 to have a plurality of recesses 3262. It should be noted that a vertical LED can be formed by disposing an electrode 344 on the transparent conductive layer 330 of the LED 300. Moreover, another electrode 342 can be disposed on the second surface 310b of the conductive substrate 310, so as to make the electrodes 342 and 344 apply a bias on the LED 300 to cause the active layer 324 emit light.

In view of the above, in the LED of the present invention (no matter a planar LED or a vertical LED), a portion of the transparent conductive layer and the second type doped semiconductor layer underneath the transparent conductive layer are removed by etching, so as to make the transparent conductive layer to be a mesh structure and the surface of the second type doped semiconductor layer to be a rough surface. Accordingly, the occurrence of total internal reflection inside the LED is reduced, thus enhancing the light extraction efficiency and the luminous efficiency of the LED. Further, as current flows into the semiconductor layer through the transparent conductive layer of a mesh structure, the current can be distributed more uniformly, thus enhancing the total luminous efficiency of the LED.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light-emitting diode (LED) structure, comprising:
a substrate;
a first type doped semiconductor layer disposed on the substrate;
an active layer disposed on the first type doped semiconductor layer;
a second type doped semiconductor layer disposed on the active layer, wherein a surface of the second type doped semiconductor layer has a plurality of recesses;
a transparent conductive layer disposed on the surface of the second type doped semiconductor layer, wherein the transparent conductive layer has a plurality of openings, such that each of the recesses of the second type doped semiconductor layer is exposed from one of the openings, respectively;
a first electrode disposed on the first type doped semiconductor layer and being electrically connected to the first type doped semiconductor layer; and
a second electrode disposed on the transparent conductive layer and being electrically connected to the transparent conductive layer, wherein the first electrode and the second electrode are electrically isolated from each other.

2. The LED structure according to claim 1, wherein a material of the substrate comprises one of Si, glass, GaAs, GaN, AlGaAs, GaP, SiC, InP, BN, ZnO, Al₂O₃ or AlN.

3. The LED structure according to claim 1, wherein the first type doped semiconductor layer is an N-type semiconductor layer, and the second type doped semiconductor layer is a P-type semiconductor layer.

4. The LED structure according to claim 1, wherein the first type doped semiconductor layer comprises:
a buffer layer disposed on the substrate;
a first contact layer disposed on the buffer layer; and
a first confinement layer disposed on the first contact layer.

5. The LED structure according to claim 1, wherein the active layer comprises a multiple quantum well (MQW) structure.

6. The LED structure according to claim 1, wherein the material of the transparent conductive layer is selected from a group consisting of Ni/Au, TiN, Pd/Au/Pt/Au, ITO, CTO, AgInO₂/Sn, ZnO:Al (AZO), NiO/ZnO:Al (AZO), AgInO₂:Sn, In₂O₃:Zn (IZO), CuAlO₂, LaCuOS, NiO, CuGaO₂, and SrCu₂O₂.

7. The LED structure according to claim 1, wherein the transparent conductive layer is of a mesh structure.

8. The LED structure according to claim 1, wherein a sidewall of each of the recesses of the transparent conductive layer is aligned with a sidewall of the corresponding opening.

9. The LED structure according to claim 1, wherein each of the openings exposes a portion of the surface of the second type doped semiconductor layer.

10. The LED structure according to claim 1, wherein a surface of the recess exposed by each opening of the transparent conductive layer is a rough surface.

11. An LED structure, comprising:
a conductive substrate having a first surface and a second surface;
a first type doped semiconductor layer disposed on the first surface of the conductive substrate;
an active layer disposed on the first type doped semiconductor layer;
a second type doped semiconductor layer disposed on the active layer, wherein a surface of the second type doped semiconductor layer has a plurality of recesses;
a transparent conductive layer disposed on the surface of the second type doped semiconductor layer, wherein the transparent conductive layer has a plurality of openings to make each recess of the second type doped semiconductor layer exposed from one of the openings; and
an electrode disposed on the transparent conductive layer and being electrically connected to the transparent conductive layer.

12. The LED structure according to claim 11, further comprising another electrode disposed on the second surface of the conductive substrate.

13. The LED structure according to claim 11, wherein the conductive substrate comprises a Si substrate, a SiC substrate, a GaN substrate, a ZnO substrate, or an Al₂O₃ substrate.

14. The LED structure according to claim 11, wherein the first type doped semiconductor layer is an N-type semiconductor layer, and the second type doped semiconductor layer is a P-type semiconductor layer.

15. The LED structure according to claim 11, wherein the first type doped semiconductor layer comprises:
a buffer layer disposed on the conductive substrate;
a first contact layer disposed on the buffer layer; and
a first confinement layer disposed on the first contact layer.

16. The LED structure according to claim 11, wherein the active layer comprises an MQW structure.

17. The LED structure according to claim 11, wherein the material of the transparent conductive layer is selected from a group consisting of Ni/Au, TiN, Pd/Au/Pt/Au, ITO, CTO, AgInO₂/Sn, ZnO:Al (AZO), NiO/ZnO:Al (AZO), AgInO₂:Sn, In₂O₃:Zn (IZO), CuAlO₂, LaCuOS, NiO, CuGaO₂, and SrCu₂O₂.

18. The LED structure according to claim 11, wherein the transparent conductive layer is of a mesh structure.

19. The LED structure according to claim 11, wherein a sidewall of each of the recesses of the transparent conductive layer is aligned with a sidewall of the corresponding opening.

20. The LED structure according to claim 11, wherein each of the openings exposes a portion of the surface of the second type doped semiconductor layer.

21. The LED structure according to claim 11, wherein a surface of the recess exposed by each opening of the transparent conductive layer is a rough surface.
